(19) United States
(12) Patent Application Publication
(10) Pub. No.: US 2015/0123160 A1
(43) Pub. Date: May 7, 2015

(54) FLIP CHIP LIGHT-EMITTING DIODE PACKAGE STRUCTURE

(71) Applicant: TEKCORE CO., LTD., Nantou (TW)

(72) Inventors: Hai-Wen Hsu, Nantou (TW); Hsin-Hsiang Tseng, Nantou (TW); Ruei-Ming Yang, Nantou (TW)

(73) Assignee: TEKCORE CO., LTD., Nantou (TW)

(21) Appl. No.: 14/072,915

(22) Filed: Nov. 6, 2013

(51) Int. Cl. H01L 33/38; H01L 33/48

(52) U.S. Cl. CPC H01L 33/38; H01L 33/48
USPC 257/99

(57) ABSTRACT

A flip chip light-emitting diode (LED) package structure includes a circuit board, an electrical conducting layer and a plurality of flip chip light-emitting elements. The circuit board includes a bearing surface. The electrical conducting layer is formed on the bearing surface, and includes a plurality of electrical connection regions independent of each other. Each flip chip light-emitting element includes a p-type electrode and an n-type electrode. The p-type electrodes and the n-type electrodes of the flip chip light-emitting elements are electrically connected to the electrical connection regions, so that the flip chip light-emitting elements are electrically connected in series to form a package structure. During packaging of the flip chip light-emitting elements, the structure formed by the serial connection forms a circuit that can withstand a high voltage, and further reduce the current.

### FIELD OF THE INVENTION

The present invention relates to a light-emitting diode (LED), and particularly to an LED package structure.

### BACKGROUND OF THE INVENTION

FIG. 1 shows a flip chip light-emitting diode (LED) disclosed by U.S. Pat. No. 7,554,126. The flip chip LED includes a pn junction between an n-type semiconductor layer 1 and a p-type semiconductor layer 2. The n-type semiconductor layer 1 and the p-type semiconductor layer 2 are connected to a solder 5 via an n-electrode 3 and a p-electrode 4 respectively. The n-electrode 3 and the p-electrode 4 are separated and insulated from each other by an insulating layer 6. The solder 5 is electrically connected to a fixed electrode 8 on a circuit board 7 to provide the flip chip LED with a required voltage.

According to the above structure, by disposing the n-electrode 3 and the p-electrode 4 at the same side of the flip chip LED, light loss resulted by metal shielding is solved and light extraction efficiency is effectively enhanced to thus promote light-emitting performance.

Further, to increase the light-emitting intensity and to reduce power consumption of an LED, in a conventional solution, a driving voltage is increased to lower the amount of current. In the prior art, to increase driving voltage, a plurality of packaged LEDs are connected in series in a positive-negative connection to form a circuit structure that can withstand a high voltage. Accordingly, the LED structure can be driven by a high voltage to lower the amount of current. However, such method yields a large volume that consumes much space, and suffers from unstable light-emitting effects as it is easily affected by external electrostatic fields.

In another conventional solution, different LEDs are directly connected in series on a wafer structure when manufacturing LED semiconductor stacked layers, and the formed structure is then cut and packaged. Such method, although having an advantage of high integration and thus a minimized volume, semiconductor processes are complicated to result in unsatisfactory yield rate and increased costs.

### SUMMARY OF THE INVENTION

Therefore the primary object of the present invention is to disclose a flip chip light-emitting diode (LED) package structure, in which a plurality of LEDs are connected in series through a package structure to withstand high voltage.

To achieve the above object, a flip chip LED package structure of the present invention includes a circuit board, an electrical conducting layer, and a plurality of flip chip light-emitting elements. The circuit board includes a bearing surface. The electrical conducting layer is formed on the bearing surface, and includes a plurality of electrical connection regions independent of each other. Each flip chip light-emitting element includes a p-type electrode and an n-type electrode. The p-type electrodes and the n-type electrodes of the flip chip light-emitting elements are electrically connected to the plurality of electrical connection regions, so that the flip chip light-emitting elements are electrically connected in series.

Accordingly, during packaging of the flip chip light-emitting elements, the structure formed by the serial connection may form a circuit that can withstand a high voltage, such that the flip chip LED package structure may be driven by a high voltage to lower the current and thus to increase the light-emitting intensity and reduce power consumption. Meanwhile, as space utilization is optimized and the front-end semiconductor process does not need to be changed, the flip chip LED package structure of the present invention can be made at a small volume and low manufacturing costs.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a structural diagram of a conventional flip chip LED;

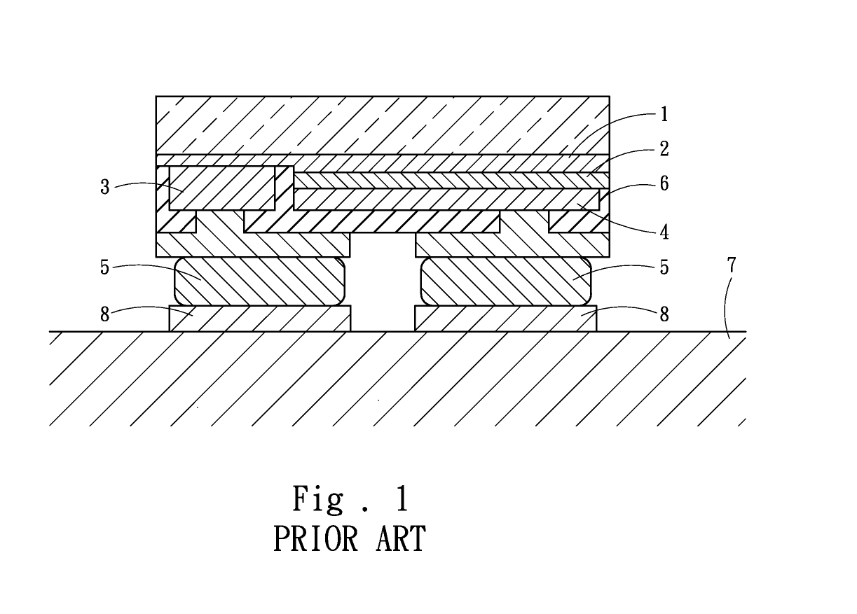

FIG. 2 is a structural diagram of the present invention; and

FIG. 3 is a top view of an electrode layer of the present invention.

### DETAILED DESCRIPTION OF THE PREFERRED EMBODIMENTS

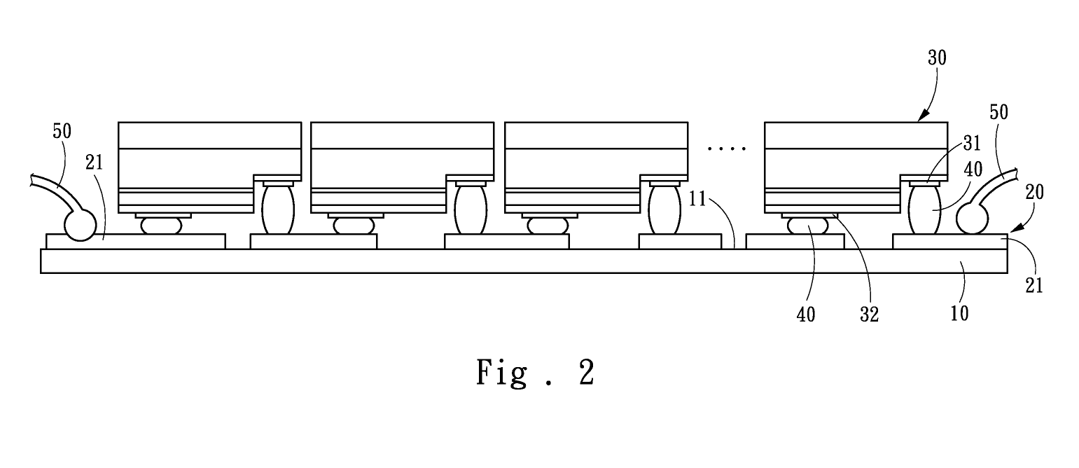

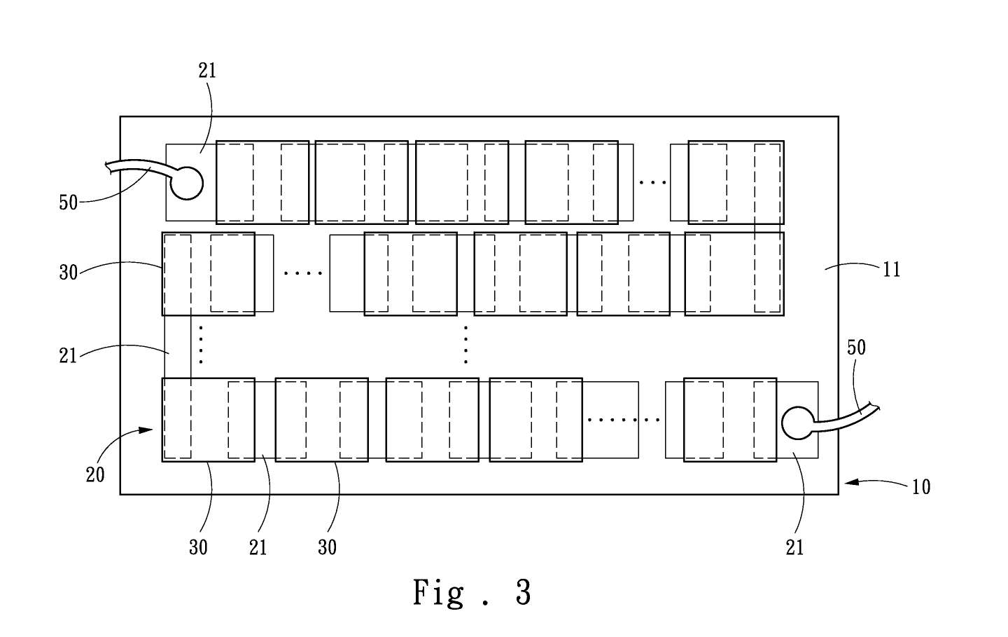

Referring to FIGS. 2 and 3, a flip chip LED package structure of the present invention includes a circuit board 10, an electrical conducting layer 20 and a plurality of flip chip light-emitting elements 30. The circuit board 10 includes a bearing surface 11. The electrical conducting layer 20 is formed on the bearing surface 11, and includes a plurality of electrical connection regions 21 independent of each other. More specifically, the plurality of electrical connection regions 21 are electrically independent, and are for electrically connecting the plurality of flip chip light-emitting elements 30.

Each flip chip light-emitting element 30 includes a p-type electrode 31 and an n-type electrode 32. The p-type electrodes 31 and the n-type electrodes 32 of the plurality of flip chip light-emitting elements 30 are electrically connected to the plurality of electrical connection regions 21, so that the plurality of flip chip light-emitting elements 30 are electrically connected in series. Further, the p-type electrodes 31 and the n-type electrodes 32 of the plurality of flip chip light-emitting elements 30 may be disposed at two sides of a surface of the flip chip light-emitting element 30, so as to effectively utilize space, reduce areas of the plurality of electrical connection regions 21 and lower material costs.

The p-type electrode 31 and the n-type electrode 32 of each of the plurality of flip chip light-emitting elements 30 are fastened and electrically connected to the corresponding electrical connection regions 21 via a solder ball 40 respectively. The height of the solder balls 40 may be modified based on actual requirements. As shown in FIG. 2, the height of the solder balls 40 coupling the p-type electrodes 31 is greater than the height of the solder balls 40 coupling the n-type electrodes 32. In practice, the plurality of flip to chip light-emitting elements 30 may be arranged on the bearing surface 11 of the circuit board 10 in a matrix to effectively utilize the space of the circuit board 10.

Further, the foremost and rearmost electrical connection regions 21 may be connected to an external power supply (not shown) via a bonding wire 50 respectively. The bonding wires 50 are the only revealed elements in the package structure, and are for connecting with an external power supply to provide the voltage required for driving the plurality of flip chip light-emitting elements 30.

As described in the above disclosure, in the present invention, during packaging of the plurality of flip chip light-emitting elements, a structure of the flip chip light-emitting elements connected in series forms a circuit that can withstand a high voltage. Therefore, the plurality of flip chip light-emitting elements connected in series can be driven by a high voltage provided by the external power supply. Given that the power stays unchanged, the high voltage in equivalence represents a low current, thereby capably reducing the current, increasing the light-emitting intensity and lowering power consumption. Further, in the structure of the present invention, the plurality of flip chip light-emitting elements are closely arranged to one another to effectively utilize space. Moreover, the plurality of flip chip light-emitting elements of the present invention may employ a common standardized product. That is, without changing the front-end semiconductor process, the flip chip LED package structure of the present invention can be made at a small volume and low manufacturing costs.

What is claimed is:

1. A flip chip light-emitting diode (LED) package structure, comprising:
a circuit board, comprising a bearing surface;
an electrical conducting layer, formed on the bearing surface, and comprising a plurality of electrical connection regions independent of each other; and
a plurality of flip chip light-emitting elements, each comprising a p-type electrode and an n-type electrode, wherein the p-type electrodes and the n-type electrodes are electrically connected to the electrical connection regions to electrically connect the plurality of flip chip light-emitting elements in series.

2. The flip chip LED package structure of claim 1, wherein the p-type electrode and the n-type electrode of each of the plurality of flip chip light-emitting elements are fastened and electrically connected to the electrical connection regions via solder balls respectively.

3. The flip chip LED package structure of claim 1, wherein the p-type electrode and the n-type electrode of each of the plurality of flip chip light-emitting elements are disposed at two sides of a surface of the flip chip light-emitting element.

4. The flip chip LED package structure of claim 1, wherein the plurality of flip chip light-emitting elements are arranged on the bearing surface of the circuit board in a matrix.

5. The flip chip LED package structure of claim 1, wherein the foremost and rearmost electrical connection regions are connected to an external power supply via a bonding wire respectively.
